(19) United States
(12) Patent Application Publication
(10) Pub. No.: US 2006/0097265 A1
(43) Pub. Date: May 11, 2006

(54) Thin film transistor array panel and method for manufacturing the same

(75) Inventors: Chang-Oh Jeong, Gyeonggi-do (KR); Beom-Seok Cho, Seoul (KR)

Correspondence Address: David W. Heid;MacPHERSON KWOK CHEN & HEID LLP, Suite 226, 1762 Technology Drive, San Jose, CA, 95110, US

(73) Assignee: SAMSUNG ELECTRONICS CO., LTD., Suwon-si (KR)

(21) Appl. No.: 11/271,143

(22) Filed: Nov. 9, 2005

(30) Foreign Application Priority Data
Nov. 9, 2004 (KR) 10-2004-0090959

(51) Int. Cl. H01L 29/04; H01L 21/84

(52) U.S. Cl. 257/72; 257/59; 438/149; 438/151

(57) ABSTRACT

Disclosed is a thin film transistor array panel comprising an insulating substrate and a gate line formed on the insulating substrate. The gate line includes a first metal layer that contains aluminum (Al), a first cover layer formed on the gate line and a gate insulating layer formed on the cover layer. A semiconductor layer is provided on a predetermined portion of the gate insulating layer and a data line is formed on the gate insulating layer and the semiconductor layer. The semiconductor layer includes a source electrode, a drain electrode spaced apart from the source electrode by a predetermined distance. A pixel electrode connected to the electrode is provided.

### CROSS REFERENCE TO RELATED APPLICATION

This Application claims priority from a Korean patent application number 10-2004-0090959 filed on Nov. 9, 2004, the contents of which are incorporated by reference herein in its entirety.

### BACKGROUND OF THE INVENTION

(a) Field of the Invention

The present description relates to a thin film transistor (TFT) array panel for a liquid crystal display (LCD) or an organic light emitting display (OLED) and a manufacturing method for the same.

(b) Description of the Related Art

Liquid crystal displays (LCDs) are one of the most widely used flat panel displays. An LCD includes a liquid crystal (LC) layer interposed between two panels provided with field-generating electrodes. The LCDs display images by applying voltages to the field-generating electrodes to generate an electric field in the LC layer that determines orientations of LC molecules in the LC layer to adjust polarization of incident light. LCDs of the type which include two panels provided with field-generating electrodes respectively, wherein one panel has a plurality of pixel electrodes in a matrix and the other has a common electrode covering the entire surface of the panel dominate the LCD market.

The LCD displays images by applying a different voltage to each pixel electrode. For this purpose, thin film transistors (TFTs), having three terminals to switch voltages applied to the pixel electrodes, are connected to the pixel electrodes, and gate lines to transmit signals for controlling the thin film transistors and data lines to transmit voltages applied to the pixel electrodes are formed on a thin film transistor array panel.

A TFT is a switching element for transmitting the image signals from the data wire to the pixel electrode in response to the scanning signals from the gate wire.

The TFT is applied to an active matrix organic light emitting display as a switching element for controlling respective light emitting elements.

Cromium (Cr) is conventionally the predominant material used for the gate line and the data line of a TFT array panel. However, Cr has the disadvantages of high stress and resistivity. As LCDs become larger, a material having low resistivity is desirable because of the increased lengths of the gate and data lines of the LCD. Accordingly, the use of Cr is not desirable for a large LCDs.

Aluminum (Al) is a well known material which can be substituted for Cr due to its low resistivity. However, Al has certain disadvantages, such as the formation of hillock protuberances at high temperatures. To overcome this disadvantage, an Al-alloy has been used. However, Al-alloys have a higher resistivity than pure Al and therefore do not provide good performance.

### SUMMARY OF THE INVENTION

To solve such problems, the present invention provides a thin film transistor array panel having wiring structures which avoid the hillock deformation when subject to high temperatures, and also exhibit a low resistance characteristic. A method manufacturing the same is also provided.

The present invention provides a thin film transistor array panel comprising; an insulating substrate; a gate line formed on the insulating substrate and including a first metal layer that contains aluminum (Al); a first cover layer formed on the gate line; a gate insulating layer formed on the cover layer; a semiconductor formed on a predetermined portion of the gate insulating layer; a data line formed on the gate insulating layer and the semiconductor layer and having a source electrode; a drain electrode facing the source electrode with a predetermined gap; and a pixel electrode connected to the pixel electrode.

The present invention provides a method of manufacturing a thin film transistor array panel comprising: forming a gate line having a first metal layer containing aluminum (Al) and having a gate electrode; forming a first cover layer formed on the gate line; sequentially depositing a gate insulating layer, a semiconductor layer and an ohmic contact layer; forming a data line and a drain electrode formed on the gate insulating layer and the ohmic contact layer, the data line having a source electrode and the drain electrode facing the source electrode with a predetermined gap; and forming a pixel electrode connected to the drain electrode.

### BRIEF DESCRIPTION OF THE DRAWINGS

FIG. 1 is a layout view of a TFT array panel for an LCD according to an embodiment of the present invention;

FIG. 2 is a sectional view of the TFT array panel shown in FIG. 1 taken along the line II-II;

FIGS. 3A, 4A, 5A, and 6A are layout views sequentially illustrating the intermediate steps of a method of manufacturing a TFT array panel for an LCD according to the embodiment of FIGS. 1 and 2;

FIG. 3B is a sectional view of the TFT array panel shown in FIG. 3A taken along the line IIIb-IIIb′;

FIG. 4B is a sectional view of the TFT array panel shown in FIG. 4A taken along the line IVb-IVb′ in the step following the step shown in FIG. 3B;

FIG. 5B is a sectional view of the TFT array panel shown in FIG. 5A taken along the line Vb-Vb′ in the step following the step shown in FIG. 4B;

FIG. 6B is a sectional view of the TFT array panel shown in FIG. 6A taken along the line VIb-VIb′ in the step following the step shown in FIG. 5B;

FIG. 7A is a picture of a gate line and storage line having hillock protrusions which extend upwardly from the surface; and

FIG. 7B is a picture of a gate line and a storage line without hillock protrusions.

### DETAILED DESCRIPTION OF THE PREFERRED EMBODIMENTS

Preferred embodiments of the present invention are described hereinafter with reference to the accompanying drawings, in which preferred embodiments of the invention are shown. The present invention may, however, be embodied in different forms and should not be construed as being limited to the embodiments set forth herein. Rather, these embodiments are provided so that this disclosure will be thorough and complete, and will fully convey the scope of the invention to those skilled in the art.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present.

TFT array panels and manufacturing methods thereof according to embodiments of this invention are described in detail with reference to the accompanying drawings for a person of ordinary skill in the art to easily carry out.

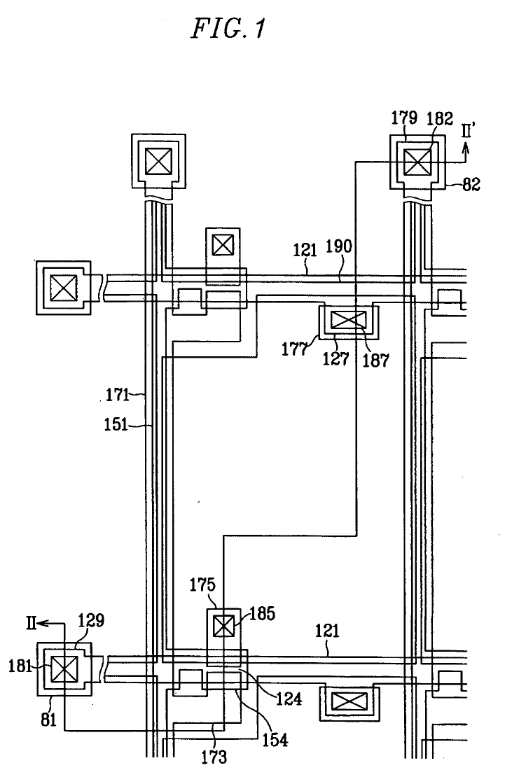

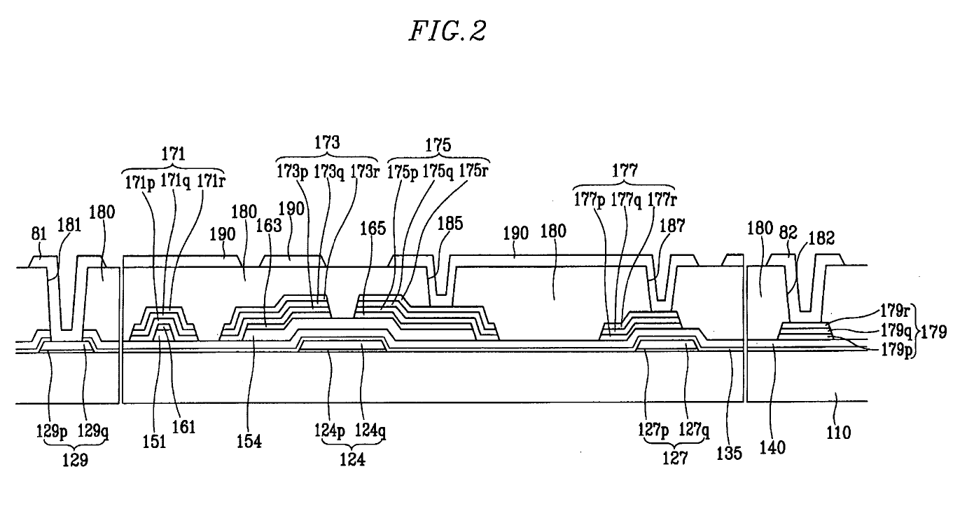

A TFT array panel for an LCD according to an embodiment of the present invention is described in detail with reference to FIGS. 1 and 2.

FIG. 1 is a layout view of a TFT array panel for an LCD according to an embodiment of the present invention and FIG. 2 is a sectional view of the TFT array panel shown in FIG. 1 taken along the line II-II.

A plurality of gate lines 121 for transmitting gate signals are formed on an insulating substrate 110. The gate lines 121 are mainly formed in the horizontal direction and partial portions thereof become a plurality of gate electrodes 124. Also, different partial portions thereof that extend in a lower direction become a plurality of expansions 127.

The gate line 121 has lower layers 124p, 127p and 129p and upper layers 124q, 127q and 129q. The lower layers 124p, 127p and 129p are made of one of chromium (Cr), molybdenum (Mo), titanium (Ti), tantalum (Ta) and their alloys. The upper layers 124q, 127q and 129q are made of pure Al. As used herein, pure Al means Al having purity over 99.99 atomic percent The upper layers 124q, 127q and 129q ensure low resistance of the gate line 121. The lower layers 124p, 127p and 129p enhance adhesiveness between the substrate 110 and the upper layers 124q, 127q and 129q.

The lateral sides of the upper layers 124q, 127q and 129q and lower layers 124p, 127p and 129p are inclined relative to a surface of the substrate 110, and the inclination angle thereof ranges about 30-80 degrees.

A cover layer 135 is formed on the gate line 121. The cover layer 135 is formed of an insulating material such as a SiNₓ or SiO₂ to a thickness of between 100 Å to 1,500 Å.

The cover layer 135 preferably has a thickness of about 500 Å. Cover layer 135 prevents the upper layers 124q, 127q and 129q from deforming during later processing steps having hillock.

Aluminum (Al) has a lower resistivity than other metals such as chromium (Cr), titanium (Ti), and molybdenum (Mo). However, aluminum (Al) has the disadvantage of deforming when high temperature processes, such as (i) forming a gate insulating layer, (ii) forming a semiconductor layer, and (iii) forming an ohmic contact layer, are performed after forming an aluminum (Al) layer on a substrate. The hillocks protrusions are formed on the surface of the Al layer by a migration of atoms to release stress between the substrate and the Al layer. These protrusions are induced by heating over 300 degrees centigrade and cooling the substrate and the Al layer which has a different thermal expansivity from the substrate.

Occurrence of the hillock protrusions makes it undesirable to us pure Al to a real production process. Accordingly, other metals having rather high resistivity or aluminum (Al) alloys which contain other metals such as neodymium (Nd) have been used. However, the aluminum alloys as well as other metal have rather high resistivity. For example, aluminum-neodymium (Al—Nd) has a resistivity 30% to 40% higher than pure aluminum. Accordingly using other metals or aluminum alloys results in an undesirable high resistance for the signal wires.

In the present invention, to prevent hillock protrusions from occurring by high temperature processes after forming a signal wire with pure aluminum, a cover layer 135 is formed on the upper layer 124q, 127q and 129q.

The cover layer 135 is formed by depositing a SiNₓ layer at a low temperature. The cover layer 135 protects the upper layer 124q, 127q and 129q from high temperature processes such as forming a gate insulating layer 140, which is performed after the application of the cover layer.

A gate insulating layer 140 is formed on the cover layer 135.

A plurality of semiconductor stripes 151, preferably made of hydrogenated amorphous silicon (abbreviated to “a-Si”), are formed on the gate insulating layer 140. Each semiconductor stripe 151 extends substantially in the longitudinal direction and is curved periodically. Each semiconductor stripe 151 has a plurality of projections 154 which branch out toward the gate electrodes 124. The width of each semiconductor stripe 151 becomes large near the gate lines 121 such that the semiconductor stripe 151 covers large areas of the gate lines 121.

A plurality of ohmic contact islands 163 and 165, preferably made of silicide or n+ hydrogenated a-Si heavily doped with n type impurity, are formed on the semiconductor stripes 151. Each of the ohmic contact islands 163 and 165 are located in pairs on the projections 154 of the semiconductor stripes 151.

The edge surfaces of the semiconductor stripes 151and the ohmic contacts 163 and 165 are tapered, and the inclination angles of the edge surfaces of the semiconductor stripes 151 and the ohmic contacts 161 and 165 are preferably in a range of about 30-80 degrees.

A plurality of data lines 171, a plurality of drain electrodes 175, and a plurality of storage capacitor conductors 177 are formed on the ohmic contacts 163 and 165 and the gate insulating layer 140.

The data lines 171, for transmitting data voltages, extend substantially in the longitudinal direction and intersect the gate lines 121. A plurality of branches of each data line 171, which project toward the drain electrodes 175, form a plurality of source electrodes 173. Each pair of the source electrodes 173 and the drain electrodes 175 are separated from each other at on the gate electrodes 124, and oppose each other.

The data line 171, the drain electrode 175, and the storage capacitor conductor 177 may be formed to have a single layer structure or a double or a triple layer structure in consideration of a resistivity and adhesiveness. In the present invention, the data line 171, the drain electrode 175, and the storage capacitor conductor 177 have first layers 171p, 173p, 175p, and 177p, second layers 171q, 173q, 175q, and 177q, and third layers 171r, 173r, 175r, and 177r. The first layers 171p, 173p, 175p, and 177p and the third layers 171r, 173r, 175r, and 177r are respectively disposed at lower and upper sides of the second layers 171q, 173q, 175q, and 177q. The second layers 171q, 173q, 175q, and 177q contain Al.

When the data line 171 is formed of pure aluminum, a cover layer for protecting the aluminum layer may be formed like the cover layer 135 of the gate line 121. As used herein, pure Al means Al having purity over 99.99 at %.

A gate electrode 124, a source electrode 173, and a drain electrode 175, along with a projection 154 of a semiconductor stripe 151, forms a TFT having a channel formed in the projection 154 disposed between the source electrode 173 and the drain electrode 175. The storage capacitor conductor 177 is overlapped with the expansion 127 of the gate line 121.

The data lines 171, the drain electrodes 175, and the storage capacitor conductor 177 have tapered edge surfaces, and the inclination angles of the edge surfaces are in a range of about 30-80 degrees.

The ohmic contacts 163 and 165 are only interposed between the semiconductor stripe 151 and the data line 171 and between the drain electrode 175 and the projection 154 of the semiconductor stripe 151 in order to reduce contact resistance therebetween. The semiconductor stripe 151 is partially exposed at the place between the source electrode 173 and the drain electrode 175 and at the other places not covered with the data line 171 and the drain electrode 175. Most of the semiconductor stripe 151 is narrower than the data line 171, but the width of the semiconductor stripe 151 broadens near a place where the semiconductor stripe 151 and the gate line 121 meet each other in order to prevent disconnection of the data line 171, as mentioned in the above.

On the data line 171, the drain electrode 175, the storage capacitor conductor 177, and the exposed region of the semiconductor stripe 151, a passivation layer 180 is provided, which is made of an inorganic material such as SiNₓ or an organic material having substantial planarization properties and photosensibility or an insulating material with a low dielectric constant such as a-Si:C:O, a-Si:O:F or other similar materials. This passivation layer 180 is formed by plasma enhanced chemical vapor deposition (PECVD). To prevent the organic material of the passivation layer 180 from contacting with the semiconductor strips 151 exposed between the data line 171 and the drain electrode 175, the passivation layer 180 can be structured in a way that an insulating layer made of SiNₓ or SiO₂ is additionally formed under the organic material layer.

In the passivation layer 180, a plurality of contact holes 181, 185, 187, and 182 are formed to expose the end of the gate line 129, the drain electrode 175, the storage capacitor conductor 177, and an end portion of the data line 171 respectively.

A plurality of pixel electrodes 190 and a plurality of contact assistants 81, 82, which are made of IZO or ITO, are formed on the passivation layer 180.

Since the pixel electrode 190 is physically and electrically connected with the drain electrode 175 and the storage capacitor conductor 177 through the contact holes 185 and 187, respectively, the pixel electrode 190 receives the data voltage from the drain electrodes 175 and transmits it to the storage capacitor conductor 177.

The pixel electrode 190 to which the data voltage is applied, generates an electric field with a common electrode (not illustrated) of an opposite panel (not illustrated) to which a common voltage is applied, so that the liquid crystal molecules in the liquid crystal layer are rearranged.

Also, as mentioned in the above, the pixel electrode 190 and the common electrode form a capacitor to store and preserve the received voltage after the TFT is turned off. This capacitor will be referred to as a” liquid crystal capacitor.” To enhance the voltage storage ability, another capacitor is provided, which is connected with the liquid crystal capacitor in parallel and will be referred to as a “storage capacitor.” The storage capacitor is formed at an overlapping portion of the pixel electrode 190 and the adjacent gate line 121, which will be referred to as “previous gate line.” The expansion 127 of the gate line 121 is provided to ensure the largest possible overlap dimension and thus to increase storage capacity of the storage capacitor. The storage capacitor conductor 177 is connected to the pixel electrode 190 and is overlapped with the expansion 127, and is provided at the bottom of the passivation layer 180 so that the pixel electrode 190 becomes close to the previous gate line 121.

The pixel electrode 190 is overlapped with the adjacent gate line 121 and the adjacent data line 171 to enhance the aperture ratio, but it is not necessarily so.

The contact assistants 81 and 82 are respectively connected to the end portion 129 of the gate line 121 and the end portion 179 of the data line 171. The contact assistants 81 and 82 supplement adhesion between the end portion of the gate line 121 and the data line 171 and the exterior devices, such as the driving integrated circuit, and protect them. Applying the contact assistants 81 and 82 is optional since it is not an essential element.

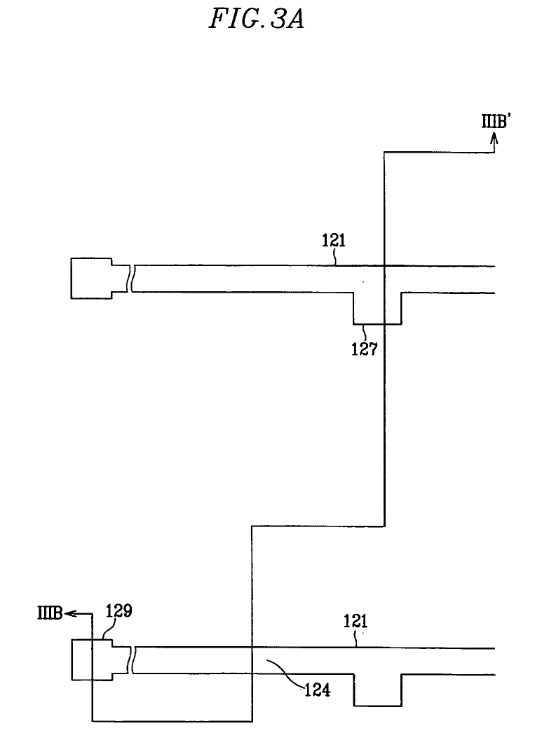

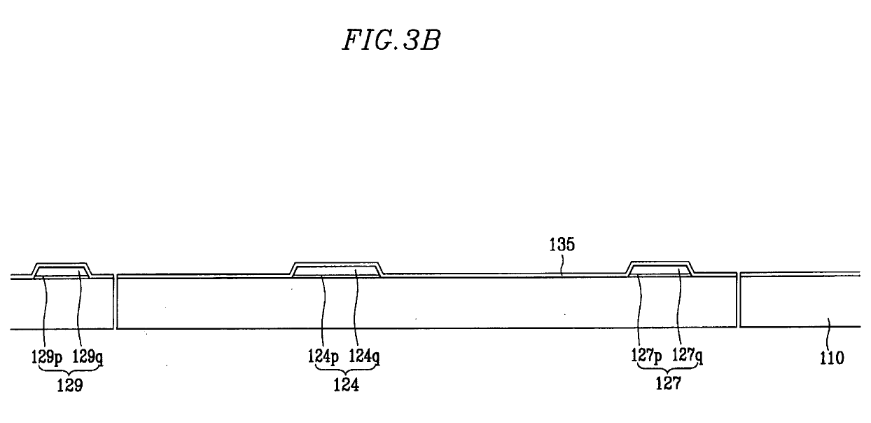

A method of manufacturing a TFT array panel will be now described in detail with reference to FIGS. 3A to 6B as well as FIGS. 1 and 2.

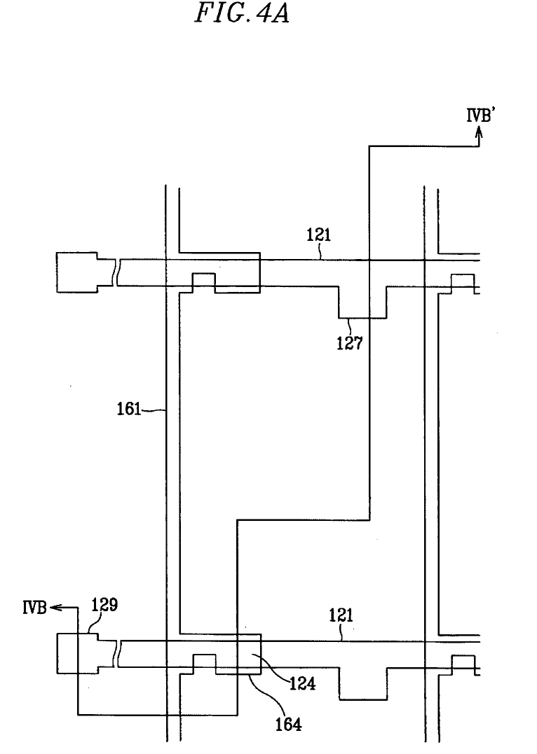

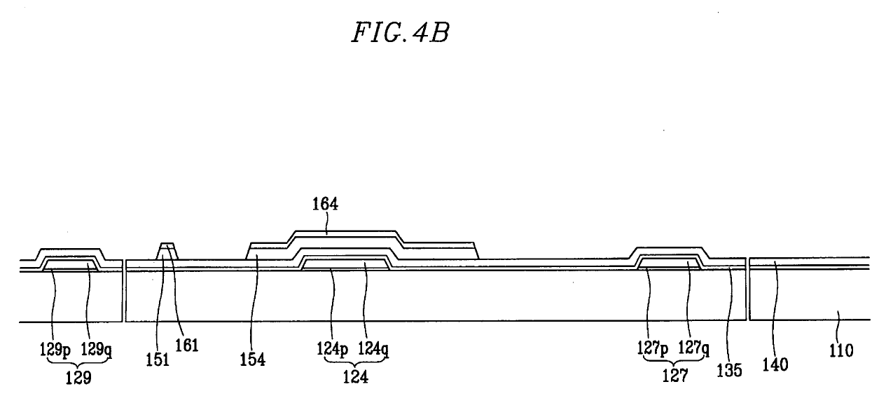

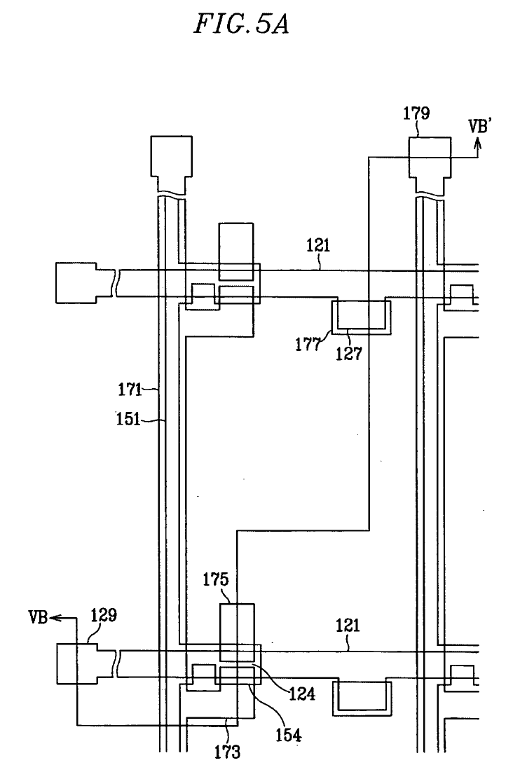

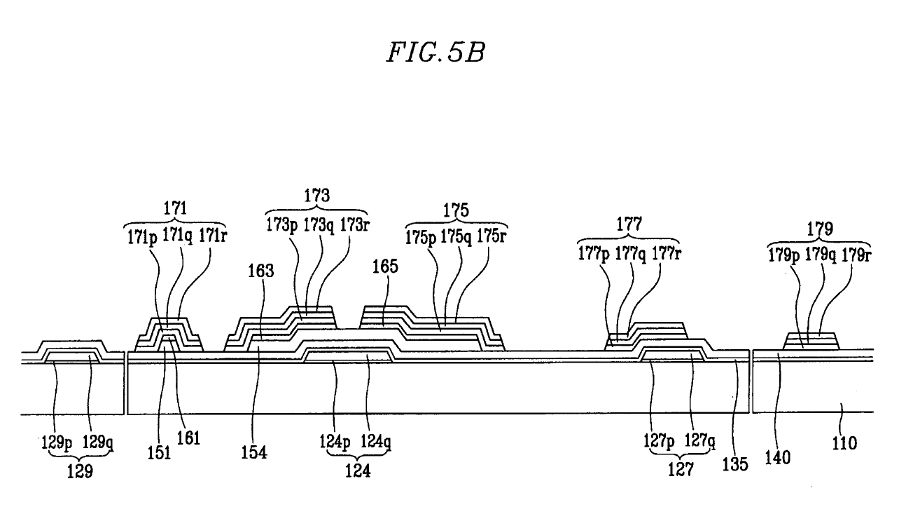

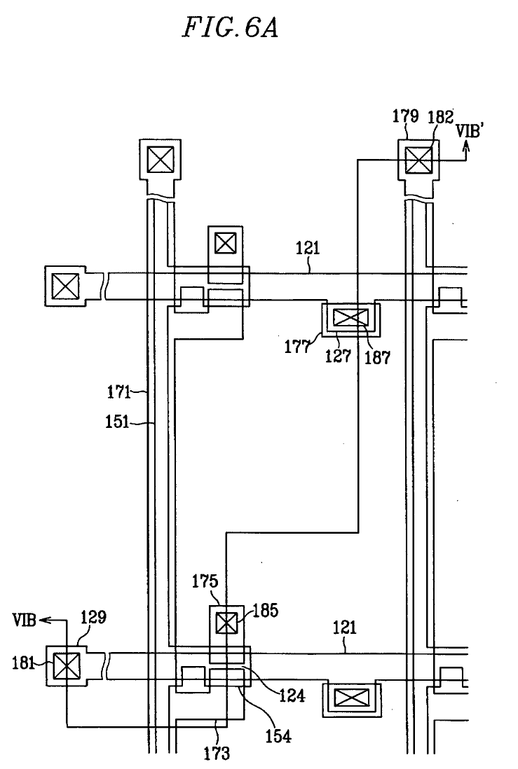

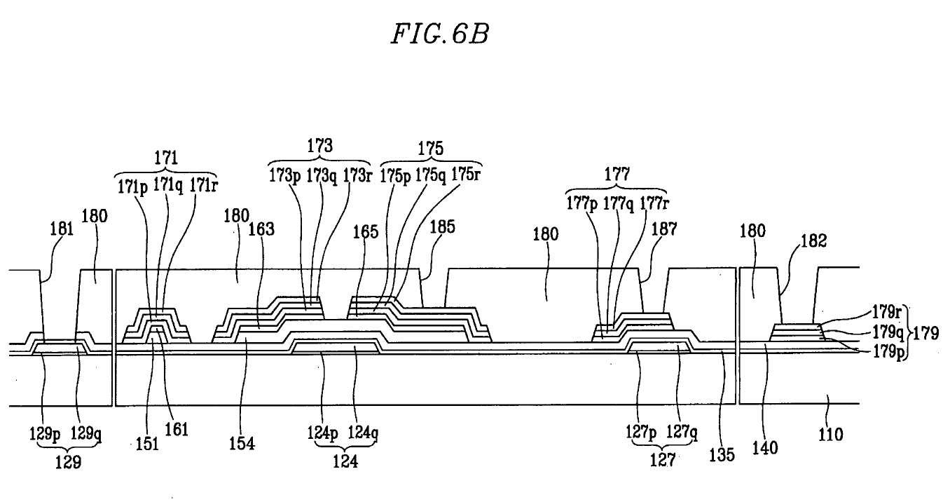

FIGS. 3A, 4A, 5A, and 6A are layout views sequentially illustrating the intermediate steps of a method of manufacturing a TFT array panel for an LCD according to the embodiment of FIGS. 1 and 2; FIG. 3B is a sectional view of the TFT array panel shown in FIG. 3A taken along the line IIIb-IIIb′. FIG. 4B is a sectional view of the TFT array panel shown in FIG. 4A taken along the line IVb-IVb′ in the step following the step shown in FIG. 3B. FIG. 5B is a sectional view of the TFT array panel shown in FIG. 5A taken along the line Vb-Vb′ in the step following the step shown in FIG. 4B. FIG. 6B is a sectional view of the TFT array panel shown in FIG. 6A taken along the line VIb-VIb′ in the step following the step shown in FIG. 5B.

At first, as shown in FIGS. 3A and 3B, metal layers are formed on an insulating substrate 110.

The metal layer is deposited by a Co-sputtering. Two targets are installed in a same sputtering chamber for the Co-sputtering. One target is made of Cr. The other target is made of Al. At first, power is applied to the Cr target while no power is applied to the Al target to deposit lower layers 124p, 127p and 129p of Cr. Here, the lower layers 124p, 127p and 129p may be formed with other metals such as Mo, Ti, Ta and their alloys, which have good adhesiveness to the substrate 110. The thickness of the lower layers 124p, 127p and 129p is preferably 400 ÅA-600 Å.

Next, power is switched to be applied to the Al target and not to be applied to the Cr target to deposit upper layers 124q, 127q and 129q. The thickness of the upper layers 124q, 127q and 129q is preferably 2,000 Å-2,500 Å.

Next, the upper layers 124q, 127q and 129q are preferably etched by an etchant containing phosphoric acid, nitric acid, acetic acid, and deionized water. Precisely, the etchant may include 63% to 70% of phosphoric acid, 4% to 8% of nitric acid, 16% to 20% of acetic acid, and deionized water for the residual quantity. Then, the lower layers 124q, 127q and 129q are etched.

Next, a SiNₓ is deposited on the gate line 121 to form a cover layer 135. The cover layer 135 is formed by plasma enhanced chemical vapor deposition at a temperature between about 100° C. to 250° C., preferably 150° C. The cover layer 135 is formed to have a thickness between 100 Å and 1,500 Å, preferably 500 Å.

The cover layer 135 prevents the hillocks protrusions from forming on the upper layer 124q, 127q and 129q.

Aluminum (Al) has a lower resistivity than other metals such as chromium (Cr), titanium (Ti), and molybdenum (Mo). However, the use of aluminum (Al) is disadvantageous because of the formation of hillocks when high temperature processes are performed after forming an aluminum (Al) layer on a substrate. Occurrence of the hillock protrusions makes is undesirable to use pure Al in a real production process. Accordingly, aluminum (Al) alloys which contain other metals such as neodymium (Nd) were used. However, the aluminum alloys have rather high resistivity. For example, aluminum-neodymium (Al—Nd) has a resistivity 30% to 40% higher than pure aluminum. Accordingly, using aluminum alloys does not provide low resistance signal wires.

In the present invention, to prevent hillock deformities from occurring as a result of high temperature processes which are performed after forming a signal wire with pure aluminum, a cover layer 135 is formed on the upper layer 124q, 127q and 129q before depositing a gate insulating layer 140, a semiconductor layer 151 and an ohmic contact layer 161. Since the cover layer 135 is formed at a low temperature about 150° C., hillocks are not formed on the upper layer 124q, 127q and 129q. Then, the cover layer 135 prevents hillock protrusions from being formed on the upper layer 124q, 127q and 129q during high temperature processes performed afterward.

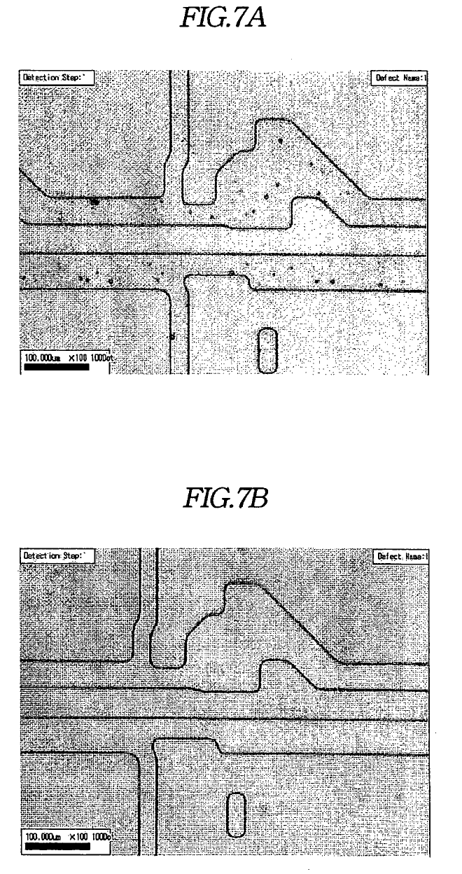

FIG. 7A is a picture of a gate line and storage line having hillock protrusions, and FIG. 7B is a picture of a gate line and storage line without hillock.

FIG. 7A is a picture of a gate line and storage line without a cover layer. Hillocks which are shown as black stains are observed after sequential depositions of a gate insulating layer, a semiconductor layer and an ohmic contact layer at a temperature about 300° C.

To the contrary, FIG. 7B is a picture of gate line and storage line with the cover layer which is deposited at a temperature about 150° C. Hillock protrusions are not observed after sequential depositions of a gate insulating layer, a semiconductor layer and an ohmic contact layer at a temperature about 300° C.

According to FIGS. 7A and 7B, it will be appreciated that the cover layer prevents hillock protrusions from being formed on a pure Al layer.

Referring to FIGS. 4A and 4B, a gate insulating layer 140 is formed on the cover layer. The gate insulating layer 140 is deposited by a chemical vapor deposition at a temperature about 300° C. to 500° C. Here, the gate insulating layer 140 is formed to have a thickness from 4,000 Å A to 6,000 Å.

Then, after sequential deposition of an intrinsic a-Si layer and an extrinsic a-Si layer on the gate insulating layer 140, the extrinsic a-Si layer and the intrinsic a-Si layer are photo-etched to form a plurality of extrinsic semiconductor pattern 164 and a plurality of intrinsic semiconductor stripes 151. The deposition temperature is in a range between about 300° C. and about 500° C.

Next, referring to FIGS. 5A and 5B, the metal layer is deposited on the extrinsic semiconductor pattern 164 by a method such as sputtering. The metal layer may be formed to have a single layer structure. However the metal layer has preferably a double or a triple layer structure to reduce resistivity and increase adhesiveness. When the metal layer has the double layer structure, the metal layer may include a lower layer of Cr and an upper layer of Al. When the metal layer is a triple layer structure, the metal layer may include a first layer containing Mo, a second layer containing Al and a third layer containing Mo. The combined thickness of the three layers is preferably about 3,000 Å. The sputtering temperature is preferably about 150° C.

Next, the three layers are simultaneously etched to form data lines 171, drain electrodes 175, and storage conductors 177 by an etchant

Next, portions of the extrinsic semiconductor patterns 164, which are not covered with the data lines 171 and the drain electrodes 175, are removed by etching to complete a plurality of ohmic contacts 163 and 165 and to expose portions of the intrinsic semiconductor stripes 151. Oxygen plasma treatment may follow thereafter in order to stabilize the exposed surfaces of the semiconductor stripes 151.

Here, when the data line 171 is made of pure Al, a cover layer (not illustrated) may be formed to protect the pure Al layer.

Next, referring to FIGS. 6A and 6B, a passivation layer 180 is deposited by coating an organic material having substantial planarization properties and photosensitivity or an insulating material with a low dielectric constant such as a-Si:C:O, a Si:O:F or depositing an inorganic material such as SiNₓ. The passivation layer 180 may be formed as a single layer or double layers. The passivation layer 180 is deposited at a temperature from about 250° C. to 300° C.

Then, the passivation layer 180 is patterned by using a photoresist layer coated on the passivation layer 180. After illuminating a light to the photoresist layer through a photo-mask, the photoresist layer is developed. The passivation layer 180 is etched by using the photoresist pattern as an etch mask to form contact holes 181, 185, 187 and 182. Here, when the passivation layer 180 is made of a photosensitive material, the contact holes may be formed just by performing photolithography. Etching for forming contact holes preferably has a condition of the same etch ratio with respect to the gate insulating layer 140 and the passivation layer 180.

Finally, as shown in FIGS. 1 and 2, a plurality of pixel electrodes 190 and a plurality of contact assistants 81 and 82 are formed by sputtering and photo-etching an IZO layer or an ITO layer.

In the described embodiment of the preset invention, the lower layers 124p, 127p and 129p are formed of Cr. However, the lower layers 124p, 127p and 129p may be formed with other metals such as Mo, Ti, Ta and their alloys, which have good adhesiveness to the substrate 110.

As described above, when a cover layer is formed on a pure Al wire, hillocks protrusions are prevented from being formed, and accordingly the use of Al with its low resistance characteristic is possible. The present invention also has effects of reducing production time and cost.

Although preferred embodiments of the present invention have been described in detail hereinabove, it should be clearly understood that many variations and/or modifications of the basic inventive concepts herein taught, which may appear to those skilled in the present art, will still fall within the spirit and scope of the present invention, as defined in the appended claims.

What is claimed is:

1. A thin film transistor array panel comprising:
an insulating substrate;
a gate line formed on the insulating substrate, the gate line being comprised of a first metal layer that includes aluminum (Al);
a first cover layer formed on the gate line;
a gate insulating layer formed on the cover layer;
a semiconductor formed on a predetermined portion of the gate insulating layer;
a data line formed on the gate insulating layer and the semiconductor layer, the data line including a source electrode;
a drain electrode facing the source electrode, wherein an edge of the drain electrode is spaced from an edge of the source electrode by a predetermined distance; and
a pixel electrode connected to the drain electrode.

2. The thin film transistor array panel of claim 1, wherein the first metal layer is comprised of aluminum having a purity of greater than 99.9 atomic percent.

3. The thin film transistor array panel of claim 1, further comprising a second metal layer formed beneath the first metal layer.

4. The thin film transistor array panel of claim 3, wherein the second metal layer is selected from the group consisting of chromium (Cr), molybdenum (Mo), titanium (Ti), tantalum (Ta) and their alloys.

5. The thin film transistor array panel of claim 3, wherein the first metal layer has a thickness greater than a thickness of the second metal layer.

6. The thin film transistor array panel of claim 1, wherein the first cover layer is comprised of a layer of electrically insulative material.

7. The thin film transistor array panel of claim 6, wherein the layer of electrically insulative material is a layer of SiNₓ.

8. The thin film transistor array according to claim 7, wherein the layer of SiNₓ is formed at a temperature between 100° C. and 250° C.

9. The thin film transistor array panel of claim 1, wherein the first cover layer is comprised of SiNₓ or SiO₂.

10. The thin film transistor array panel of claim 9, wherein the SiNₓ layer is formed at a temperature between 100° C. and 250° C.

11. The thin film transistor array panel of claim 1, wherein the first cover layer has a thickness of between 100 Å and 1,500 Å

12. The thin film transistor array panel of claim 1, wherein the data line and the drain electrode include a metal layer containing aluminum (Al).

13. The thin film transistor array panel of claim 1, further comprising an ohmic contact layer formed on the semiconductor layer.

14. The thin film transistor array panel of claim 1, further comprising a second cover layer formed on the data line and drain electrode.

15. The thin film transistor array panel of claim 14, wherein the second cover layer is comprised of a layer of electrically insulative material.

16. The thin film transistor array panel of claim 15, wherein the second cover layer is comprised of SiNₓ.

17. The thin film transistor array panel of claim 16, wherein the SiNₓ layer is formed at a temperature between 100° C. and 250° C.

18. The thin film transistor array panel according to claim 14, wherein the second cover layer is comprised of SiNₓ or SiO₂.

19. A method of manufacturing a thin film transistor array panel comprising:
forming a gate line having a first metal layer which includes aluminum (Al), the gate line including a gate electrode;
forming a first cover layer on the gate line;
sequentially depositing a gate insulating layer, a semiconductor layer and an ohmic contact layer;
forming a data line and a drain electrode on the gate insulating layer and the ohmic contact layer, the data line including a source electrode, wherein an edge of the drain electrode faces an edge of the source electrode and is spaced from an edge of the source electrode by a predetermined distance; and
forming a pixel electrode connected to the drain electrode.

20. The method of claim 19, wherein the first metal layer is comprised of aluminum having a purity greater than 99.99 atomic percent.

21. The method of claim 19, further comprising forming a second metal layer using a material selected from the group consisting of with one of Cr, Mo, Ti, Ta and their alloy before the formation of the first metal layer.

22. The method of claim 21, wherein the first metal layer is deposited to have a thickness between 400 Å and 600 Å and the second metal layer is deposited to have a thickness between 2,000 Å and 2,500 Å.

23. The method of claim 19, wherein the first cover layer is formed by a process performed at a temperature lower than that of forming the gate insulating layer, the semiconductor layer and the ohmic contact layer.

24. The method of claim 23, wherein the first cover layer is formed at a temperature between 100° C. and 250° C.

25. The method of claim 24, wherein the first cover layer is a SiNₓ layer formed by plasma enhanced chemical vapor deposition.

26. The method of claim 19, wherein the first cover layer is formed to a thickness of between 1000 Å and 1,500 Å.

27. The method of claim 19, further comprising forming a second cover layer on the data line and the drain electrode.

28. A thin film transistor array panel comprising:
an insulating substrate;
a gate line formed on the insulating substrate;
a gate insulating layer formed on the gate line;
a semiconductor formed on a predetermined portion of the gate insulating layer;
a data line formed on the gate insulating layer and the semiconductor layer, the data line being comprised of a first metal layer that includes aluminum (Al), and the data line including a source electrode;
a first cover layer formed on the data line;
a drain electrode facing the source electrode, wherein an edge of the drain electrode is spaced from an edge of the source electrode by a predetermined distance; and
a pixel electrode connected to the drain electrode.

29. The thin film transistor array panel of claim 28, wherein the first metal layer is comprised of aluminum having a purity of greater than 99.9 atomic percent.

30. The thin film transistor array panel of claim 28, further comprising a second metal layer formed beneath the first metal layer.

31. The thin film transistor array panel of claim 30, wherein the second metal layer is selected from the group consisting of chromium (Cr), molybdenum (Mo), titanium (Ti), tantalum (Ta) and their alloys.

32. The thin film transistor array panel of claim 30, wherein the first metal layer has a thickness greater than a thickness of the second metal layer.

33. The thin film transistor array panel of claim 28, wherein the first cover layer is comprised of a layer of electrically insulative material.

34. The thin film transistor array panel of claim 33, wherein the layer of electrically insulative material is a layer of SiNₓ.

35. The thin film transistor array according to claim 34, wherein the layer of SiNₓ is formed at a temperature between 100° C. and 250° C.

36. The thin film transistor array panel of claim 28, wherein the first cover layer is comprised of SiNₓ.

37. The thin film transistor array panel of claim 36, wherein the SiNₓ layer is formed at a temperature between 100° C. and 250° C.

38. The thin film transistor array panel of claim 28, wherein the first cover layer has a thickness of between 100 Å and 1,500 Å.

39. The thin film transistor array panel of claim 28, wherein the data line and the drain electrode include a metal layer containing aluminum (Al).

40. The thin film transistor array panel of claim 28, further comprising an ohmic contact layer formed on the semiconductor layer.

41. The thin film transistor array panel of claim 28, further comprising a second cover layer formed on the gate line.

42. The thin film transistor array panel of claim 41, wherein the second cover layer is comprised of a layer of electrically insulative material.

43. The thin film transistor array panel of claim 42, wherein the second cover layer is comprised of SiNₓ or SiO₂.

44. The thin film transistor array panel of claim 43, wherein the SiNₓ layer is formed at a temperature between 100° C. and 250° C.

45. The thin film transistor array panel according to claim 41, wherein the second cover layer is comprised of SiNₓ or SiO₂.

46. A method of manufacturing a thin film transistor array panel comprising:
forming a gate line, the gate line including a gate electrode;
sequentially depositing a gate insulating layer, a semiconductor layer and an ohmic contact layer;
forming a data line having a first metal layer which includes aluminum (Al) and a drain electrode on the gate insulating layer and the ohmic contact layer, the data line including a source electrode, wherein an edge of the drain electrode faces an edge of the source electrode and is spaced from an edge of the source electrode by a predetermined distance;
forming a first cover layer on the data line; and
forming a pixel electrode connected to the drain electrode.

47. The method of claim 46, wherein the first metal layer is comprised of aluminum having a purity greater than 99.99 atomic percent.

48. The method of claim 46, further comprising forming a second metal layer using a material selected from the group consisting of with one of Cr, Mo, Ti, Ta and their alloy before the formation of the first metal layer.

49. The method of claim 48, wherein the first metal layer is deposited to have a thickness between 400 Å and 600 Å and the second metal layer is deposited to have a thickness between 2,000 Å and 2,500 Å.

50. The method of claim 46, wherein the first cover layer is formed by a process performed at a temperature lower than that of forming the gate insulating layer, the semiconductor layer and the ohmic contact layer.

51. The method of claim 50, wherein the first cover layer is formed at a temperature between 100° C. and 250° C.

52. The method of claim 51, wherein the first cover layer is a SiNₓ layer formed by plasma enhanced chemical vapor deposition.

53. The method of claim 46, wherein the first cover layer is formed to a thickness of between 100 Å and 1,500 Å.

54. The method of claim 46, further comprising forming a second cover layer on the gate line.
